(19) United States
(12) Patent Application Publication
(10) Pub. No.: US 2007/0026550 A1
(43) Pub. Date: Feb. 1, 2007

(54) Method of manufacturing semiconductor light emitting apparatus and semiconductor light emitting apparatus

(75) Inventors: Masahiro Murayama, Kyoto-shi (JP); Daisuke Nakagawa, Kyoto-shi (JP); Shinichi Kohda, Kyoto-shi (JP); Toshio Nishida, Kyoto-shi (JP)

Correspondence Address: HOGAN & HARTSON L.L.P., 1999 AVENUE OF THE STARS, SUITE 1400, LOS ANGELES, CA, 90067, US

(73) Assignee: ROHM CO., LTD.

(21) Appl. No.: 11/483,314

(22) Filed: Jul. 6, 2006

(30) Foreign Application Priority Data
Jul. 12, 2005 (JP) JP2005-202556

(51) Int. Cl. H01L 21/00

(52) U.S. Cl. 438/22; 438/39; 438/46

(57) ABSTRACT

A method of manufacturing a semiconductor light emitting apparatus according to the invention includes: the mask layer forming step of forming two mask layers in descending order of etching rates from a side near a p-type semiconductor layer; the mask layer etching step; the semiconductor layer etching step; the side etching step of selectively etching a side surface of a mask layer having a high etching rate to form a groove portion in the p-type semiconductor layer; the insulating film forming step of forming an insulating film so as to cover the p-type semiconductor layer; the mask layer removing step; and the electrode layer forming step. A semiconductor light emitting apparatus according to the invention includes: a substrate; an n-type semiconductor layer; an active layer; a p-type semiconductor layer on which a mesa portion projecting above the active layer is formed; an insulating film which covers the mesa portion to expose an upper surface of the mesa portion; and an electrode layer. Then-type semiconductor layer, the active layer, and the p-type semiconductor layer are made of a Group III nitride based compound semiconductor.

The present application is based on, and claims priority from, J.P. Application 2005-202556, filed Jul. 12, 2005, the disclosure of which is hereby incorporated by reference herein in its entirety.

### BACKGROUND OF THE INVENTION

1. Field of the Invention

The present invention relates to a method of manufacturing a semiconductor light emitting apparatus having a semiconductor light emitting device and the semiconductor light emitting apparatus.

2. Description of the Related Art

A conventional semiconductor light emitting apparatus having a Group III nitride based semiconductor expressed by AlₓGa_{y}In_{1-x-y}N (where 0≦x≦1, 0≦y≦1, 0≦x+y≦1) is manufactured as follows. In this case, a procedure of manufacturing a conventional semiconductor light emitting apparatus will be described below with reference to FIGS. 7-A to 7-D and FIGS. 8-A to 8-D.

FIGS. 7-A to 7-D and FIGS. 8-A to 8-D are schematic views showing some of steps in manufacturing a semiconductor light emitting apparatus having a conventional Group III nitride based compound semiconductor expressed by AlₓGa_{y}In_{1-x-y}N (where 0≦x≦1, 0≦y≦1, 0≦x+y<1). FIGS. 7-A to 7-D and FIGS. 8-A to 8-D show schematic sections of the semiconductor light emitting apparatus in the respective steps. FIG. 9 is a schematic diagram of a semiconductor light emitting apparatus obtained by a conventional manufacturing method. FIGS. 7-A to 7-D and FIGS. 8-A to 8-D show only parts of the semiconductor light emitting apparatus required for an explanation of the method of manufacturing a semiconductor light emitting apparatus.

In manufacturing of a conventional semiconductor light emitting apparatus, as shown in FIG. 7-A, an SiO₂ film 50 is formed on an upper surface of a p-GaN contact layer 46 of a semiconductor substrate obtained by sequentially forming an n-GaN contact layer (not shown), an n-AlGaN clad layer (not shown), an n-GaN guide layer 43, an InGaN/GaN active layer 44, a p-AlGaN electronic block layer 55, a p-GaN guide layer 56, a p-AlGaN clad layer 45, and the p-GaN contact layer 46 on a substrate (not shown). Thereafter as shown in FIG. 7-B, a stripe-shaped resist pattern 51 is formed on the SiO₂ film 50.

By using the resist pattern 51 formed in FIG. 7-B as a mask, as shown in FIG. 7-C, the SiO₂ film 50 is etched. Thereafter, the resist pattern 51 is peeled. The resist pattern of the SiO₂ film 50 exposed by peeling the resist pattern 51 is used as a mask to etch the p-GaN contact layer 46, the p-AlGaN clad layer 45, and a part of the p-GaN guide layer 56 as shown in FIG. 7-D.

To form an n-type electrode layer (will be described later), as shown in FIG. 8-A, the resultant structure is dug by dry etching to expose an n-GaN contact layer 41. As shown in FIG. 8-B, an insulating film 47 is formed to cover the resist pattern of the SiO₂ film 50 and the surface of the semiconductor layer including the p-AlGaN clad layer 45 and the p-GaN contact layer 46. The reference no. 42 in FIG. 8 indicates an n-AlGaN clad layer.

Thereafter, the SiO₂ film 50 is lifted off by hydrofluoric acid treatment together with the insulating film 47 (FIG. 8-C). The insulating film 47 on a portion on which an n-type electrode layer will be deposited later is removed by dry etching to expose the n-GaN contact layer 41.

A p-type electrode layer 48 is formed to an upper surface 52 of the p-GaN contact layer 46 exposed by the liftoff and the insulating film 47 as shown in FIG. 8-D. An n-type electrode layer 49 is formed on the exposed upper surface of the n-GaN contact layer 41 and cleaved every substrate 40 to obtain a semiconductor light emitting apparatus 500 shown in FIG. 9 (for example, see Japanese Patent Application Laid-open Nos. 2000-312051 and 2003-142769).

However, in the conventional method of manufacturing a semiconductor light emitting apparatus shown in FIGS. 7-A to 7-D and FIGS. 8-A to 8-D, when the insulating film 47 shown in FIG. 8-B is formed, the insulating film 47 completely covers the SiO₂ film 50 as shown in FIG. 8-B. For this reason, an etching solution is blocked from permeating the SiO₂ film 50. For this reason, a yield of liftoff for the p-GaN contact layer 46 which is a p-type semiconductor layer is considerably low.

In a semiconductor light emitting apparatus manufactured by the conventional method of manufacturing a semiconductor light emitting apparatus, since the insulating film 47 is formed on only a side surface of a mesa portion 53 formed in the step shown in FIG. 7-D, the p-type electrode layer 48 shown in FIG. 9 is in contact with the entire upper surface 52 of the mesa portion 53. For this reason, when the semiconductor light emitting apparatus 500 is driven, as indicated by an arrow, a current from the p-type electrode layer 48 easily flows into a portion near the side surface of the mesa portion 53, and an electric field is concentrated on an edge portion 54 of the mesa portion 53. The concentration of the electric field on the edge portion 54 of the mesa portion 53 is a factor of breaking the semiconductor light emitting apparatus 500 down.

### SUMMARY OF THE INVENTION

Therefore, according to the present invention, it is an object of the present invention to provide a method of manufacturing a semiconductor light emitting apparatus which can manufacture a semiconductor light emitting apparatus in which a yield of liftoff for a p-type semiconductor layer can be increased and an electric field is suppressed from being concentrated on an edge portion-of a mesa portion on the p-type semiconductor layer by a current from the p-type electrode layer to improve a withstand voltage. It is another object of the present invention to provide the semiconductor light emitting apparatus.

In order to achieve the objects, the present inventor set the step of forming two mask layers on a p-type semiconductor layer from a side near the p-type semiconductor layers in descending order of etching rates to make it possible to form a seam of an insulating film.

More specifically, a method of manufacturing a semiconductor light emitting apparatus according to the present invention includes the mask layer forming step of forming two mask layers on a p-type semiconductor layer of a Group III nitride based compound semiconductor in which an n-type semiconductor layer, an active layer, and the p-type semiconductor layer are sequentially arranged on a substrate and which is expressed by AlₓGa_{y}In_{1-x-y}N (where 0≦x≦1, 0≦y≦1, 0≦x+y≦1) from a side near the p-type semiconductor layer; the mask layer etching step of forming a predetermined resist pattern on the two mask layers formed in the mask layer forming step, etching both the two mask layers by using the formed resist pattern as a mask, and peeling the resist pattern from the two mask layers; the semiconductor layer etching step of etching the p-type semiconductor layer by using, as a mask, a resist pattern obtained by the two mask layers formed in the mask layer etching step; the side etching step of, after the semiconductor layer etching step, selectively etching a side surface of a mask layer having a high etching rate of the two mask layers to form a groove portion from which a part of the p-type semiconductor layer is exposed; the insulating film forming step of forming an insulating film so as to cover the exposed p-type semiconductor layer of the groove portion formed in the side etching step; the mask layer removing step of, after the insulating film forming step, removing the two remaining mask layers from the p-type semiconductor layer; and the electrode layer forming step of forming an electrode layer so as to cover an entire surface of the p-type semiconductor layer exposed in the mask layer removing step.

In the mask layer forming step, the two mask layers are formed in descending order of etching rates from a side near the p-type semiconductor layer, so that the side surface of the mask layer having a high etching rate is selectively etched in the side etching step to make it possible to form a groove portion in the side surface. In the insulating film forming step, the groove serves as a shadow of the insulating film to form the insulating film in the groove portion. For this reason, the insulating film is avoided from covering the entire surface of the mask layer to make it possible to form a seam in the insulating film. For this reason, when the two mask layers are removed from the p-type semiconductor layer in the later step, the two mask layers can be lifted off at the seam. Therefore, a yield of liftoff with respect to the p-type semiconductor layer can be increased. In addition, when the insulating film fills in the groove portion, a semiconductor light emitting apparatus in which the edge portion of the mesa portion on the p-type semiconductor layer formed in the semiconductor layer etching step is covered with an insulating film to suppress electric field concentration on the edge portion to increase a withstand voltage can be manufactured.

In the mask layer forming step of the method of manufacturing a semiconductor light emitting apparatus, a ratio of etching rates of the two mask layers is preferably set at not less than 5. Furthermore, the ratio of etching rates of the two mask layers is more preferably set at not less than 10.

When the ratio of etching rates of the two mask layers is set at not less than 5, in the side etching step, an amount of etching of a mask layer having a low etching rate can be made very small, and the groove portion can be adjusted in depth. For this reason, in the insulating film forming step, an amount of filling of the insulating film in the groove portion is made sufficient, and an effect that suppresses concentration of an electric field on the edge portion of the mesa portion on the p-type semiconductor layer can be improved.

In the mask layer forming step of the method of manufacturing a semiconductor light emitting apparatus, as a mask layer having a high etching rate of the two mask layers, an oxide or a nitride which is formed by spin coating by performing thermal solidification or ultraviolet curing after the spin coating or laser abrasion is preferably used, and as a mask layer having a low etching rate of the two mask layers, an oxide or a nitride which is formed by sputtering or a plasma chemical vapor growing method is preferably used.

As the two mask layers, any mask layers described above are used to make a difference between the etching rates of the mask layers sufficient, so that an amount of etching of the mask layer having a low etching rate in the side etching step can be made very small. For this reason, in the side etching step, the groove portion can be adjusted in depth. For this reason, in the insulating film forming step, an amount of filling of the insulating film in the groove portion is made sufficient to make it possible to improve an effect that suppressing concentration of an electric field on the edge portion of the mesa portion on the p-type semiconductor layer.

In the mask layer forming step of the method of manufacturing a semiconductor light emitting apparatus, the thickness of the mask layer having a high etching rate is not less than 10 nm and not more than 500 nm.

In the mask layer forming step, the thickness of the mask layer having a high etching rate is not less than 10 nm and not more than 500 nm, an inner wall surface along an upper surface of the mesa portion of the insulating film can be made inclined to be widened upwardly. For this reason, a semiconductor light emitting apparatus in which stress concentration occurring between the insulating film and the upper surface of the mesa portion is suppressed can be manufactured. Furthermore, when the mask layer having a low etching rate is formed by sputtering or a plasma chemical vapor growing method, so that an effect that reduces plasma damage to the p-type semiconductor layer can be given to the mask layer having a high etching rate.

In the insulating film forming step of the method of manufacturing a semiconductor light emitting apparatus, the insulating film is preferably made of an oxide or a nitride of a metal or a semimetal.

All a metal oxide, a metal nitride, a semimetal oxide, and a semimetal nitride are good in insulating property, an effect that suppressing concentration of an electric field on the edge portion of the mesa portion on the p-type semiconductor layer is improved. In this case, the semimetal nitride means a material obtained by coupling a semimetal and nitrogen atoms. It is assumed that the semimetal is a material in a state in which Fermi energy traverses an uppermost portion of a valence band and a lowermost portion of a conduction band, in other words, in a state in which the uppermost portion of the valence band and the lowermost portion of the conduction band overlap (the same applies to the following specification). As the semimetal, B, C, Si, Ge, Sn, P, As, Sb, Bi, Se, Te, Po, and At can be exemplified.

The semiconductor light emitting apparatus according to the present invention includes a substrate, an n-type semiconductor layer arranged on the substrate, an active layer arranged on the n-type semiconductor layer, a p-type semiconductor layer which is arranged on the active layer and on which a mesa portion projecting above the active layer, an insulating film which covers the mesa portion from an inner side along the edge of the upper surface to a side surface of the mesa portion to expose the upper surface of the mesa portion, and an electrode layer which covers the mesa portion from above the insulating film and which is electrically connected to the p-type semiconductor layer, wherein the n-type semiconductor layer, the active layer, and the p-type semiconductor layer are made of a Group III nitride based compound semiconductor expressed by AlₓGa_{y}In_{1-x-y}N (where 0≦x≦1, 0≦y≦1, 0≦x+y≦1).

The insulating film covers the mesa portion from the inner side along the edge of the upper surface to the side surface of the mesa portion so as to expose the upper surface of the mesa portion to make it possible to suppress concentration on an electric field on the edge portion of the mesa portion on the p-type semiconductor layer by a current from the electrode layer, thereby improving the withstand voltage. For this reason, the semiconductor light emitting apparatus according to the present invention can be made high-powered.

In the semiconductor light emitting apparatus, an inner wall surface along the upper surface of the mesa portion of the insulating film is preferably inclined to be widened toward the upper side of the mesa portion.

When the wall surface of the inner side along the upper surface of the mesa portion of the insulating film is inclined to be widened toward the upper side of the mesa portion, a smooth curve is obtained between the upper surface of the mesa portion and the wall surface, concentration of stress caused by a difference between thermal expansions of the insulating film and the upper surface of the mesa portion does not occur. Therefore, a semiconductor light emitting apparatus according to the present invention can achieve a long life.

In the semiconductor light emitting apparatus, the wall surface preferably has a two-step shape.

The inner wall surface along the upper surface of the mesa portion of the insulating film has the two-step shape to make it possible to increase a thickness of the insulating film between the edge portion of the mesa portion and the electrode layer. For this reason, an insulating property between the electrode layer and the edge portion of the mesa portion by the insulating film is made sufficient to make it possible to improve an effect that suppresses concentration of an electric field on the edge portion of the mesa portion on the p-type semiconductor layer.

In the semiconductor light emitting apparatus, a width of a contact portion between the insulating film and the upper surface of the mesa portion from an edge of the upper surface of the mesa portion preferably exceeds 0 and is not more than 0.5 μm.

The width of the contact portion between the insulating film and the upper portion of the mesa portion from the edge of the upper surface of the mesa portion exceeds 0 and is not more than 0.5 μm to make it possible to improve the effect that suppressing concentration of an electric field on the edge portion of the mesa portion on the p-type semiconductor layer while assuring a sufficient amount of current flowing from the p-type electrode layer to the p-type semiconductor layer.

In the semiconductor light emitting apparatus, the insulating film is preferably made of an oxide or a nitride of a metal or a semimetal.

Since any one of the metal oxide, the metal nitride, the semimetal oxide, and the semimetal nitride has a good insulating property, the effect that suppresses concentration of an electric field on the edge portion of the mesa portion on the p-type semiconductor layer is improved.

According to the present invention, there can be provided a method of manufacturing a semiconductor light emitting apparatus which can manufacture a semiconductor light emitting apparatus which can increase an yield of liftoff to a p-type semiconductor layer and suppresses concentration of an electric field on an edge portion of a mesa portion on the p-type semiconductor layer by a current from a p-type electrode layer to increase a withstand voltage. There can be also provided a semiconductor light emitting apparatus which can suppress concentration of an electric field by a current from a p-type electrode layer to increase a withstand voltage.

### BRIEF DESCRIPTION OF THE DRAWINGS

FIGS. 1-A to 1-D are schematic diagrams showing some of steps performed until a p-type electrode layer and an n-type electrode layer are formed in a method of manufacturing a semiconductor light emitting apparatus according to one embodiment.

FIGS. 2-A to 2-D are schematic diagrams showing some of steps performed until the p-type electrode layer and the n-type electrode layer are formed in the method of manufacturing a semiconductor light emitting apparatus according to one embodiment.

FIGS. 3-A and 3-B are schematic diagrams of a semiconductor light emitting apparatus according to one embodiment.

FIGS. 4-A to 4-B are schematic diagrams of a semiconductor light emitting apparatus according to another embodiment.

FIG. 5 is an enlarged schematic sectional diagram of a mesa portion of the semiconductor light emitting apparatus according to one embodiment.

FIG. 6 is an enlarged schematic sectional diagram of a mesa portion of the semiconductor light emitting apparatus according to the other embodiment.

FIGS. 7-A to 7-D are schematic diagrams showing some of the steps in manufacturing a semiconductor light emitting apparatus having a conventional Group III nitride based compound semiconductor expressed by AlₓGa_{y}In_{1-x-y}N (where 0≦x≦1, 0≦y≦1, 0≦x+y≦1).

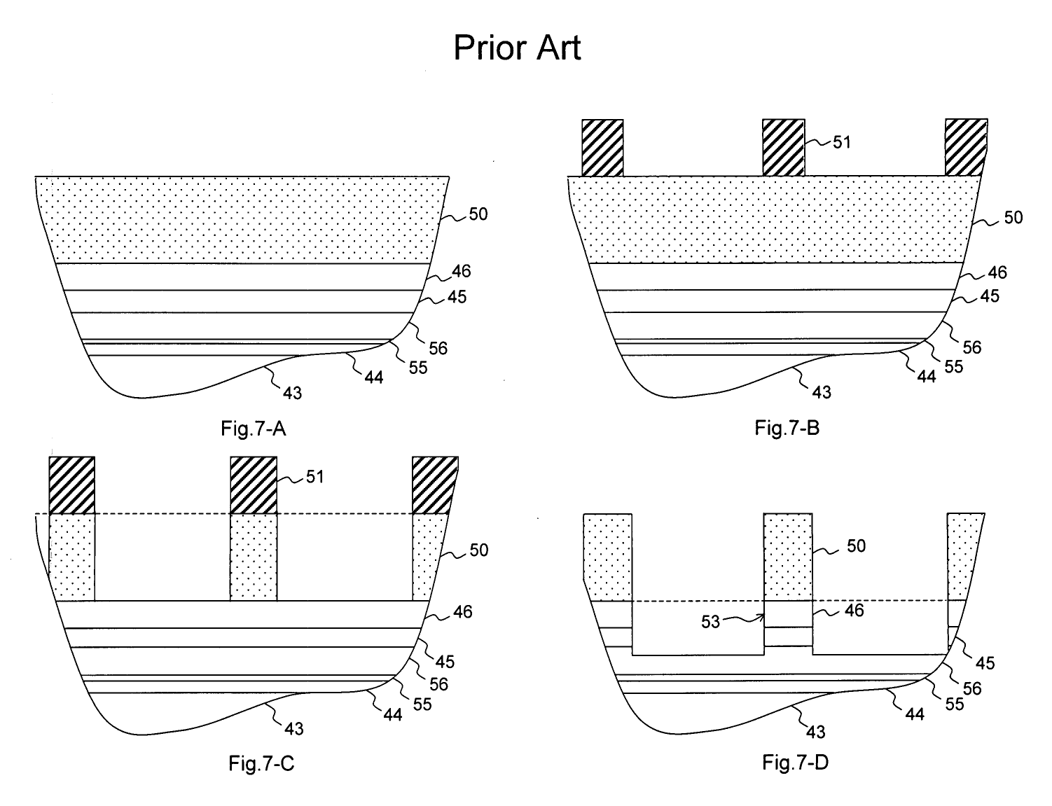

FIGS. 8-A to 8-D are schematic diagrams showing some of the steps in manufacturing a semiconductor light emitting apparatus having a conventional Group III nitride based compound semiconductor expressed by AlₓGa_{y}In_{1-x-y}N (where 0≦x≦1, 0≦y≦1, 0≦x+y≦1).

FIG. 9 is a schematic diagram of a semiconductor light emitting apparatus obtained by a conventional manufacturing method.

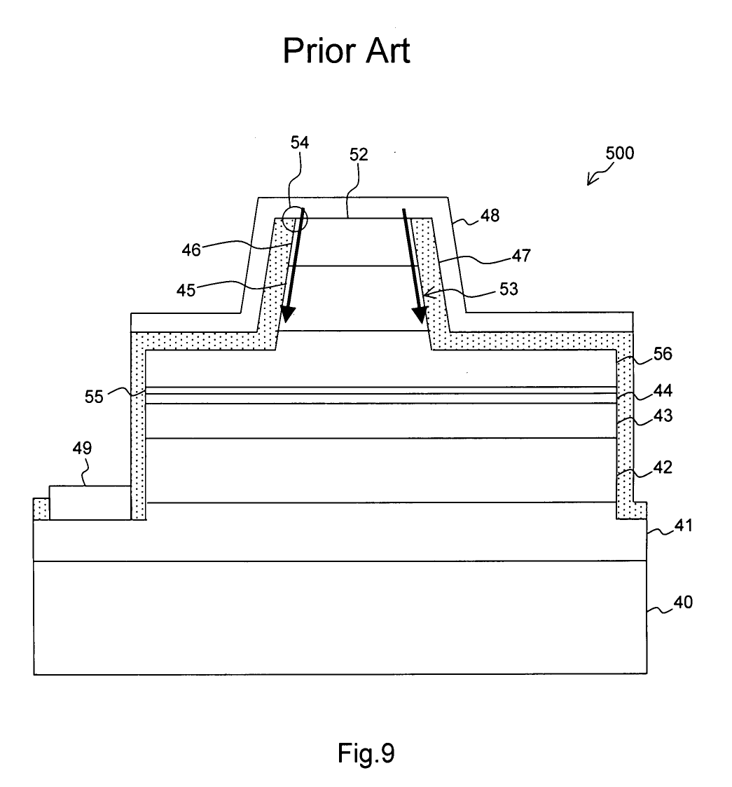

FIGS. 10-A to 10-D are schematic diagrams showing some of steps performed until a semiconductor light emitting apparatus is obtained by the method of manufacturing a semiconductor light emitting apparatus according to one embodiment.

FIGS. 11-A to 11-D are schematic diagrams showing some of steps performed until a semiconductor light emitting apparatus is obtained by the method of manufacturing a semiconductor light emitting apparatus according to one embodiment.

FIGS. 12-A to 12-D are schematic diagrams showing some of steps performed until a semiconductor light emitting apparatus is obtained by the method of manufacturing a semiconductor light emitting apparatus according to one embodiment.

FIGS. 13-A to 13-D are schematic diagrams showing some of steps performed until a semiconductor light emitting apparatus is obtained by the method of manufacturing a semiconductor light emitting apparatus according to one embodiment.

FIGS. 14-A to 14-B are schematic diagrams showing some of steps performed until a semiconductor light emitting apparatus is obtained by the method of manufacturing a semiconductor light emitting apparatus according to one embodiment.

FIG. 15 is a diagram showing potentials of respective layers of the semiconductor light emitting apparatus according to one embodiment.

### DESCRIPTION OF THE PREFERRED EMBODIMENTS

Embodiments of the present invention will be described below with reference to the accompanying drawings. The present invention is not limited to the following embodiments.

### First Embodiment

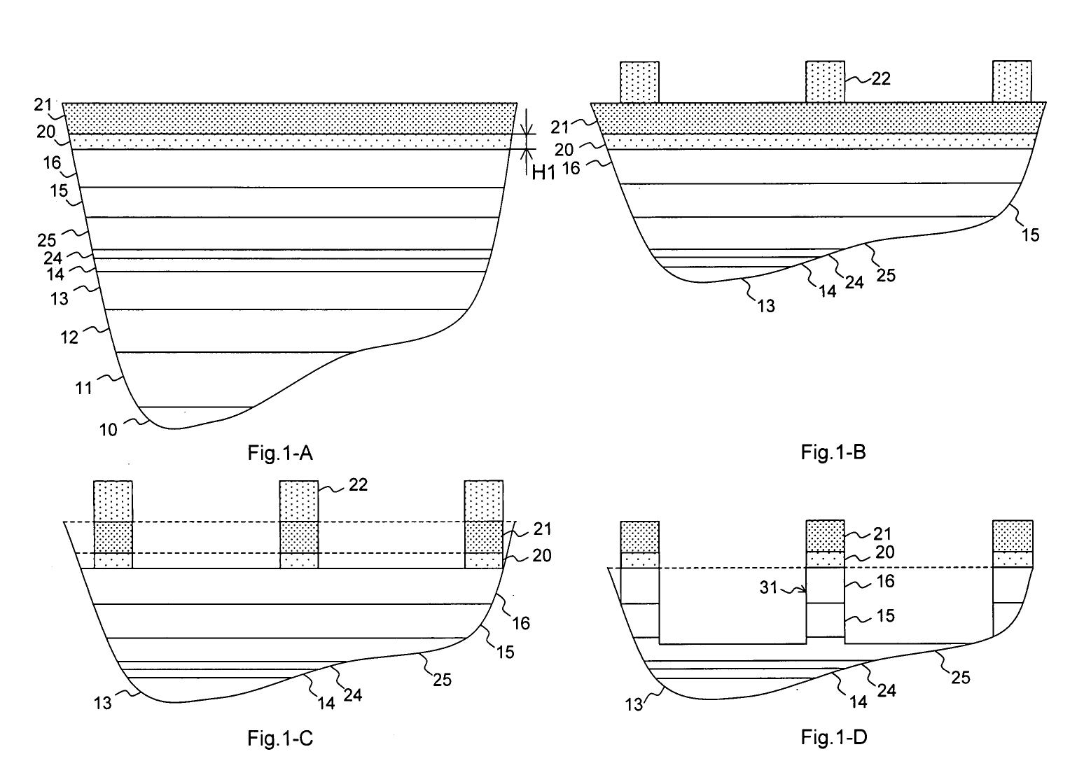

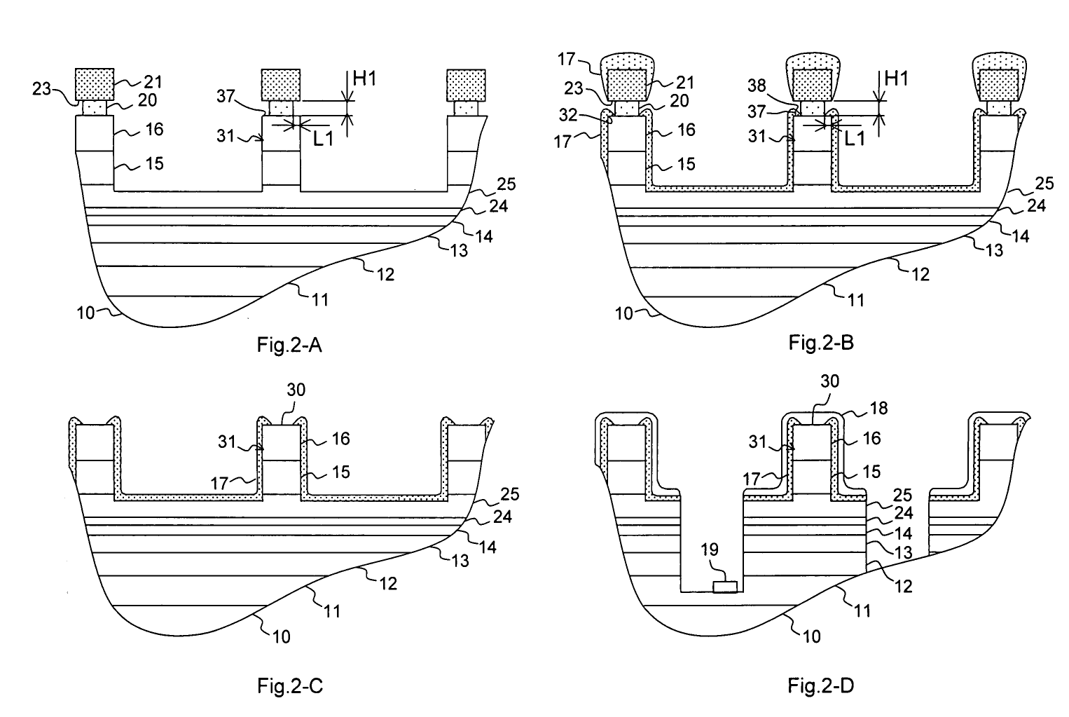

A method of manufacturing a semiconductor light emitting apparatus according to the embodiment will be described below. FIGS. 1-A to 1D and FIGS. 2-A to 2-D are schematic diagram showing steps performed until a p-type electrode layer and an n-type electrode layer are formed on a wafer of a Group III nitride based compound semiconductor expressed by AlₓGa_{y}In_{1-x-y}N (where 0≦x≦1, 0≦y≦1, 0≦x+y≦1) in the method of manufacturing a semiconductor light emitting apparatus according to the embodiment. FIGS. 1-A to 1-D and FIGS. 2-A to 2-D show schematic sectional diagrams of the semiconductor light emitting apparatus in the respective steps. In these drawings, only parts required to explain the method of manufacturing a semiconductor light emitting apparatus are described.

(Mask Layer Forming Step)

In the method of manufacturing a semiconductor light emitting apparatus according to the embodiment, a semiconductor light emitting apparatus having a Group III nitride based compound semiconductor expressed by AlₓGa_{y}In_{1-x-y}N (where 0≦x≦1, 0≦y≦1, 0≦x+y≦1) is manufactured. As shown in FIG. 1-A, on a p-GaN contact layer 16 of n-type semiconductor layers (n-GaN contact layer 11, n-AlGaN clad layer 12, and n-GaN guide layer 13), an active layer (InGaN/GaN active layer 14), and p-type semiconductor layers (p-AlGaN electron block layer 24, p-GaN guide layer 25, p-AlGaN clad layer 15, and p-GaN contact layer 16) which are sequentially arranged on a substrate 10, two mask layers (first mask layer 20 and second mask layer 21) are formed from a side near the p-GaN contact layer 16 in descending order of etching rates. In this case, as the substrate 10, for example, a sapphire substrate or a GaN substrate can be applied.

In this manner, as the two mask layers, the first mask layer 20 and the second mask layer 21 are sequentially formed from a side near the p-GaN contact layer 16 in the order named to selectively etch a side surface of the first mask layer 20 having a high etching rate in the side etching step (will be described later) to make it possible to form a groove portion in the side surface.

In this case, a ratio of etching rates of the first mask layer 20 having a high etching rate and the second mask layer 21 having a low etching rate is desirably set at 5 or more. More desirably, the ratio of etching rates is set at 10 or more. The ratio of etching rates is set at 5 or more to make an amount of etching of the second mask layer 21 having the low etching rate considerably small in the side etching step (will be described later), and the groove portion can be adjusted in depth. For this reason, in the insulating film forming step (will be described later), an amount of filling of the insulating film in the groove portion is made sufficient to make it possible to manufacture a semiconductor light emitting apparatus which can efficiently suppress concentration of an electric field on an edge portion of a mesa portion on the p-type semiconductor layer.

Of the two mask layers, the first mask layer 20 having the high etching rate is an oxide or a nitride formed by spin coating by performing thermal solidification or ultraviolet curing after spin coating or laser abrasion. Of the two mask layers, the second mask layer 21 having the low etching rate can also be an oxide or a nitride formed by sputtering or a plasma chemical vapor growing method. As a combination of the first mask layer 20 and the second mask layer 21, any one of combinations of: for example, an SiO₂ layer formed by spin coating or thermal solidification or ultraviolet curing after the spin coating and an SiO₂ layer formed by sputtering; an SiO₂ layer formed by spin coating or thermal solidification or ultraviolet curing after the spin coating and an SiO₂ layer formed by a plasma chemical vapor growing method; an SiO₂ layer formed by spin coating or thermal solidification or ultraviolet curing after the spin coating and an SiN layer formed by sputtering; an SiO₂ layer formed by spin coating or thermal solidification or ultraviolet curing after the spin coating and an SiN layer formed by a plasma chemical vapor growing method; an SiO₂ layer formed by spin coating or thermal solidification or ultraviolet curing after the spin coating and a ZrO₂ layer formed by sputtering; a ZnO layer formed by laser abrasion and an SiO₂ layer formed by sputtering; a ZnO layer formed by laser abrasion and an SiO₂ layer formed by a plasma chemical vapor growing method; a ZnO layer formed by laser abrasion and an SiN layer formed by sputtering; a ZnO layer formed by laser abrasion and an SiN layer formed by sputtering; a ZnO layer formed by laser abrasion and an SiN layer formed by a plasma chemical vapor growing method; and a ZnO layer formed by laser abrasion and a ZrO₂ layer formed by sputtering can be used.

When any one of the above combinations is selected as the combination of the first mask layer 20 and the second mask layer 21, a difference between the etching rates of both the mask layers can be made sufficient, and an amount of etching of the second mask layer 21 having the low etching rate in the side etching step (will be described later) can be made very low. For this reason, in the side etching step, the groove portion can be adjusted in depth. Therefore, in the insulating film forming step (will be described later), an amount of filling of the insulating film in the groove portion can be made sufficient to make it possible to manufacture a semiconductor light emitting apparatus which can efficiently suppress concentration of an electric field on an edge portion of the mesa portion on the p-type semiconductor layer.

Here, the “spin coating” means a coating method which coats a predetermined solution on a substrate and disperses the solution on the entire substrate while rotating the substrate. In the SiO₂ layer formed by the spin coating, a solution of a silanol compound is applied as the predetermined solution. After the spin coating, the substrate is naturally dried by being left at a room temperature or subjected to heat treatment to form the SiO₂ layer. The “sputtering” means a method which applies a high DC voltage across the substrate and a target while introducing an inert gas (mainly an argon gas) to a place in a vacuum condition, hit argon ions at the target, and a flicked target material is deposited on the substrate to form a film. The “plasma chemical vapor growing method” means a method which flows a gas-phase source gas and deposits a product on the substrate by using a chemical reaction in plasma discharging to form a film. The “laser abrasion” means a method which irradiates a laser beam from an excimer laser having an oscillation wavelength falling in a ultraviolet band onto a target and deposits evaporated particles on a substrate to form a film.

In the embodiment, as the first mask layer 20, an SiO₂ layer is formed by a sol-gel method, and, as the second mask layer 21, an SiO₂ layer is formed by sputtering. In this case, the sol-gel method is a method which heats a gel obtained by canceling fluidity of a sol made of a metal alcoxide by a hydrolysis-polycondensation reaction to obtain an oxide. According to the sol-gel method, since atomic bonds are nondense more than those in sputtering, a sufficient ratio of etching rates of the first mask layer 20 and the second mask layer 21 can be achieved.

The first mask layer 20 having the high etching rate preferably has a layer thickness H1 which is 10 nm or more and 500 nm or less. When the layer thickness H1 of the first mask layer 20 is 10 nm or more and 500 nm or less, an inner wall surface of an insulating film formed on the mesa portion in the insulating forming step (will be described later) can be inclined to be widened toward the upper side. For this reason, a semiconductor light emitting apparatus in which concentration of stress occurring between the insulating film and the upper surface of the mesa portion is suppressed can be manufactured. As in the embodiment, when the second mask layer 21 is formed by sputtering or a plasma chemical vapor growing method, an effect that reduces plasma damage to the p-GaN contact layer 16 can be given to the first mask layer 20.

(Mask Layer Etching Step)

As shown in FIG. 1-B, a predetermined resist pattern 22 is formed on the first mask layer 20 and the second mask layer 21 formed by the mask layer forming step. In the embodiment, since semiconductor light emitting apparatuses are mass-produced, a stripe-shaped resist pattern is formed. A width of each stripe is set at 1 μm to 2 μm. By using the formed resist pattern 22 as a mask, as shown in FIG. 1-C, both the first mask layer 20 and the second mask layer 21 are etched. Thereafter, the resist pattern 22 is peeled from the two layers, i.e., the first mask layer 20 and the second mask layer 21.

(Semiconductor Layer Etching Step)

By using the resist pattern obtained by the two layers, i.e., the first mask layer 20 and the second mask layer 21 formed by the mask layer etching step as a mask, as shown in FIG. 1-D, the p-GaN contact layer 16, the p-AlGaN clad layer 15, and a part of the p-GaN guide layer 25 are dry-etched. In this step, a mesa portion 31 electrically connected to a p-type electrode layer (will be described later) is formed on the p-GaN contact layer 16. In this case, when the layer thickness of the second mask layer 21 is small, the second mask layer 21 is completely removed in the dry etching. For this reason, the second mask layer 21 is formed to have a predetermined layer thickness or more in the mask layer forming step. The dry etching is a method that removes an etching target by a chemical reaction between a plasma etching gas and the etching target.

(Side Etching Step)

As shown in FIG. 2-A, a side surface of the first mask layer 20 of the two mask layers is selectively etched to form a groove portion 37 in which the p-GaN contact layer 16 is partially exposed. In the embodiment, a buffered fluorinated acid which is an ammonium hydrogen difluoride solution is used as an etching solution, and wet etching is performed such that the mesa portion 31 shown in FIG. 1-D is dipped in the etching solution for a predetermined period of time, thereby forming the groove portion 37 (FIG. 2-A). A depth L1 of the groove portion 37 is determined depending on an amount of filling of an insulating film formed in the insulating forming step (will be described later). When the ZnO layer formed by laser abrasion is applied as the first mask layer 20, a hydrochloric acid is used as an etching solution to form the groove portion 37.

(Insulating Film Forming Step)

An insulating film 17 is formed to cover the p-GaN contact layer 16 exposed in the groove portion 37 formed by the side etching step. In the embodiment, the insulating film 17 is formed by the sputtering, the plasma chemical vapor growing method, or the laser abrasion. When these methods are applied, a upper surface 23 of the groove portion 37 serves as a shadow with respect to a material of the insulating film deposited so that the material falls. For this reason, as shown in FIG. 2-B, the insulating film 17 is formed to fill in the groove portion 37. Therefore, the insulating film 17 is prevented from coating the first mask layer 20 and the second mask layer 21 to make it possible to form a seam in the insulating film 17. More specifically, a seam is formed between the insulating film 17 which covers the p-GaN contact layer 16 exposed in the groove portion 37 and the insulating film 17 covering the second mask layer 21. For this reason, in the mask layer removing step (will be described later), when the first mask layer 20 and the second mask layer 21 are removed from the p-GaN contact layer 16, the first mask layer 20 and the second mask layer 21 can be lifted off at the seam. Therefore, a yield of liftoff to the p-GaN contact layer 16 can be increased. Furthermore, the insulating film is filled in the groove portion, so that a semiconductor light emitting apparatus in which an edge portion 32 of the mesa portion 31 formed in the semiconductor layer etching step is covered with the insulating film 17 to suppress concentration of an electric field on the edge portion 32 so as to increase a withstand voltage can be manufactured. The “edge” means an outer periphery of the upper surface of the mesa portion, and the “edge portion” means an edge portion of the upper surface including the “edge”. It is assumed that the same applies to the following specification.

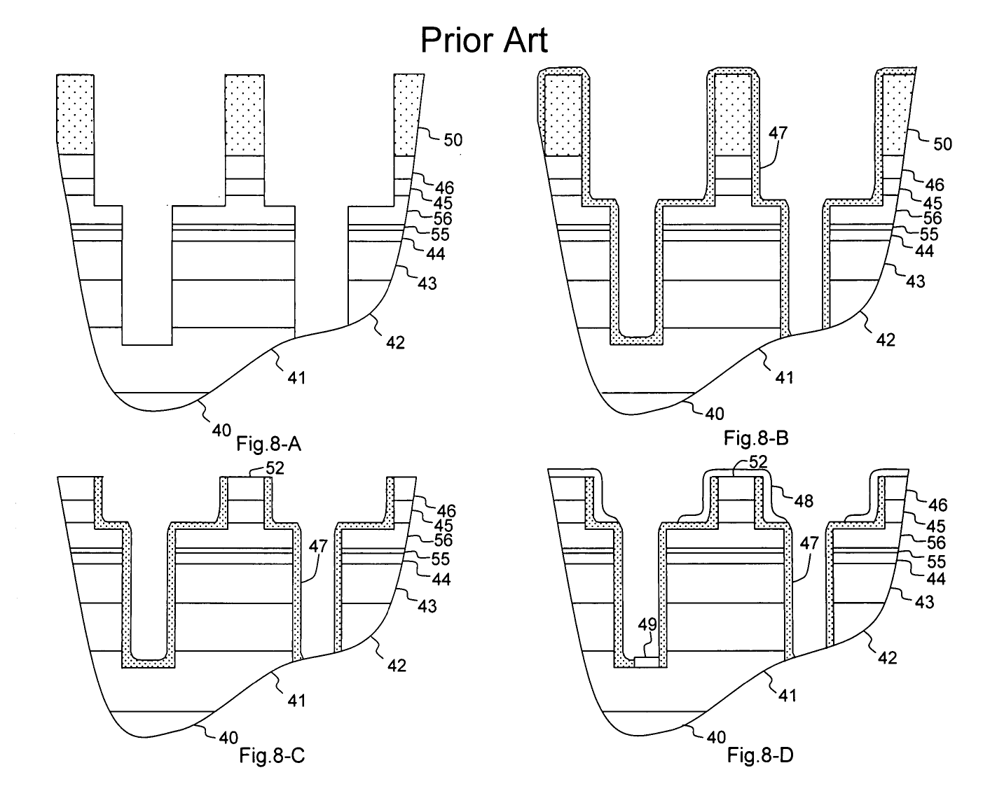

Only covering of the edge portion 32 with the insulating film 17 may be made possible by etching the side surface of the SiO₂ film 50 in, for example, FIG. 8-A in a conventional manufacturing method. The embodiment has a conspicuous advantage to that the covering of the edge portion 32 with the insulating film 17 and the increase in yield of liftoff with respect to the p-GaN contact layer 16 which is a p-type semiconductor layer can be simultaneously satisfied over a conventional technique.

In this case, the insulating film 17 is preferably made of a metal oxide or a semimetal oxide. For example, as the insulating film 17, ZrO₂ or Al₂O₃ can be applied. Since the metal oxide and the semimetal oxide are good in insulating property, concentration of an electric field on the edge portion 32 of the mesa portion 31 can be efficiently suppressed.

(Mask Layer Removing Step)

The first mask layer 20 and the second mask layer 21 are removed from the p-GaN contact layer 16 as shown in FIG. 2-C. In the embodiment, the mesa portion 31 shown in FIG. 2-B is dipped in the buffered fluorinated acid to lift off the first mask layer 20 and the second mask layer 21.

(Electrode Layer Forming Step)

A p-type electrode layer 18 is formed so as to cover the entire surface of an upper surface 30 of the p-GaN contact layer 16 exposed in the mask layer removing step as shown in FIG. 2-D. In this case, the p-type electrode layer 18 is formed as follows. That is, a portion except for a portion for forming the p-type electrode layer on the insulating film 17 is masked by a resist pattern in advance, and the layer is deposited on only the upper surface 30 and the side surface of the mesa portion 31. The layers are removed by dry etching together with the insulating film 17 to expose the n-GaN contact layer 11. An n-type electrode layer 19 is formed on the upper surface of the n-GaN contact layer 11 exposed by the liftoff. The resultant structure is dug to expose the n-GaN contact layer 11, and the n-type electrode layer 19 is formed on the exposed upper surface of the n-GaN contact layer 11. Thereafter, the substrate 10 is cleaved as a whole to obtain a semiconductor light emitting apparatus. The cleavage can be realized by thinning the substrate 10 by lapping.

In the embodiment, although the arranged portion of the n-type electrode layer 19 is formed in the electrode layer forming step. However, after or before the side etching step, in FIG. 2-A, the resultant structure may be dug to expose the n-GaN contact layer 11 to form the arranged portion of the n-type electrode layer 19.

A semiconductor light emitting apparatus according to the embodiment will be described below. The semiconductor light emitting apparatus according to the embodiment can be manufactured by the manufacturing method.

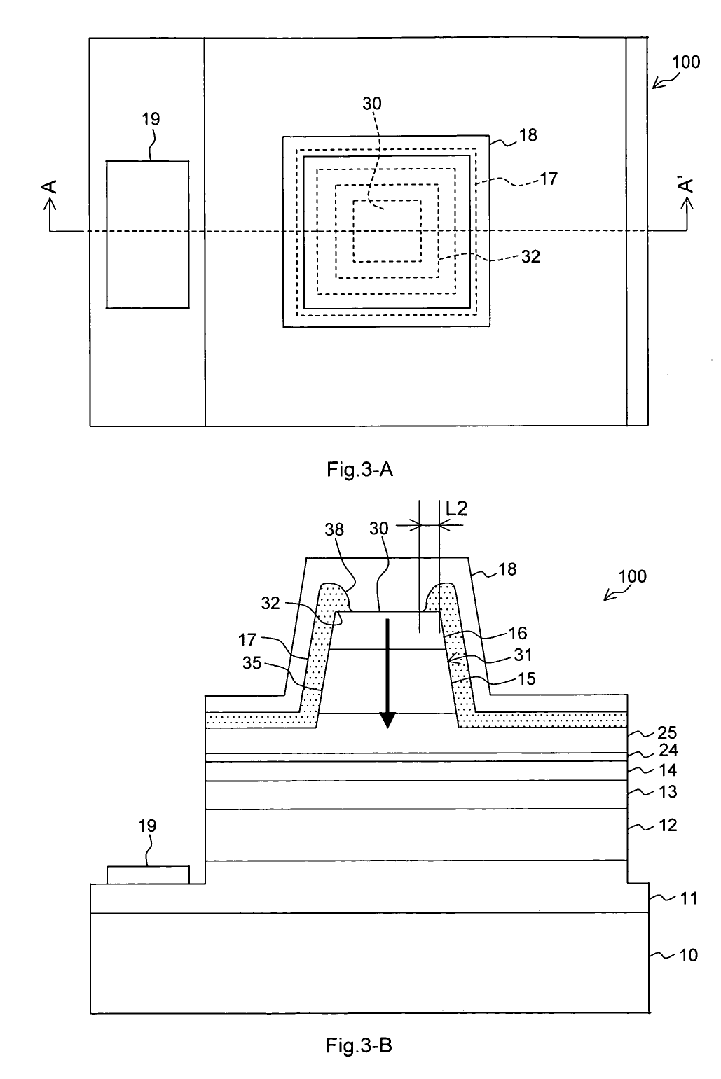

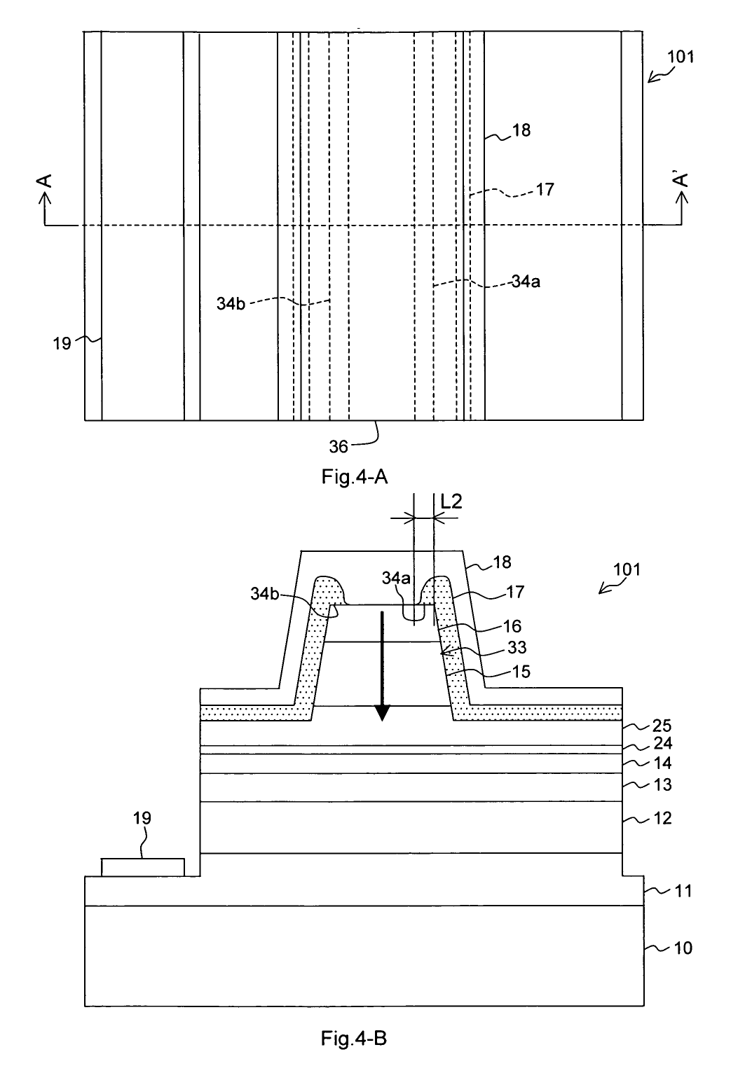

FIGS. 3-A and 3-B show schematic diagrams of the semiconductor light emitting apparatus according to the embodiment. FIG. 3-A shows a top view of the semiconductor light emitting apparatus, and FIG. 3-B shows a sectional view along an A-A′ line in FIG. 3-A. FIG. 4-A shows a top view of the semiconductor light emitting apparatus, and FIG. 4-B shows a sectional view along an A-A′ line in FIG. 4-A.

A semiconductor light emitting apparatus 100 according to the embodiment includes: a substrate 10, an n-GaN contact layer 11, an n-AlGaN clad layer 12, and an n-GaN guide layer 13 which serve as n-type semiconductor layers arranged on the substrate 10; an InGaN/GaN active layer 14 serving as an active layer arranged on the n-GaN guide layer 13; a p-AlGaN electron block layer 24, a p-GaN guide layer 25, a p-AlGaN clad layer 15, and a p-GaN contact layer 16 which are arranged on the InGaN/GaN active layer 14 and serve as p-type semiconductor layers on which a mesa portion 31 projecting above the InGaN/GaN active layer 14; an insulating film 17 which covers the mesa portion 31 from an inner side along an edge portion 32 of an upper surface 30 to a side surface 35 of the mesa portion 31 so as to expose the upper surface 30 of the mesa portion 31; a p-type electrode layer 18 which covers the mesa portion 31 from above the insulating film 17 and electrically connected to the p-GaN contact layer 16; and an n-type electrode layer 19 electrically connected to the n-GaN contact layer 11. The n-GaN contact layer 11, the n-AlGaN clad layer 12, the n-GaN guide layer 13, the InGaN/GaN active layer 14, the p-AlGaN electron block layer 24, the p-GaN guide layer 25, the p-AlGaN clad layer 15, and the p-GaN contact layer 16 are made of a Group III nitride based compound semiconductor expressed by AlₓGa_{y}In_{1-x-y}N (where 0≦x≦1, 0≦y≦1, 0≦x+y≦1).

The insulating film 17 covers the mesa portion 31 from the inner side along the edge portion 32 of the upper surface 30 to the side surface 35 of the mesa portion 31 so as to expose the upper surface 30 of the mesa portion 31, so that a central portion of the upper surface 30 of the mesa portion 31 serves as a contact portion between the p-type electrode layer 18 and the p-GaN contact layer 16. For this reason, a current from the p-type electrode layer 18 can be flown from the center of the upper surface 30 of the mesa portion 31 to the p-GaN contact layer 16 as indicated by an arrow in FIG. 3-B. For this reason, concentration of an electric field on the edge portion 32 of the mesa portion 31 caused by the current from the p-type electrode layer 18 can be suppressed, and a withstand voltage increases. Therefore, the semiconductor light emitting apparatus 100 according to the embodiment can be made high-powered.

In the embodiment, the insulating film 17, as shown in FIG. 3-A, is arranged so as to cover an outer periphery of the upper surface 30 of the mesa portion 31 along the edge portion 32 of the mesa portion 31 to expose the upper surface 30 of the mesa portion 31 in the form of a caldera. The arrangement of the insulating film 17 may be changed depending on a shape of the resist pattern 22 (FIG. 1-B) in the mask layer etching step. However, as shown in FIG. 3-A, when the insulating film 17 is arranged to cover the outer periphery of the upper surface 30 of the mesa portion 31, concentration of an electric field can be efficiently suppressed. Insulating films 17, as in a semiconductor light emitting apparatus 101 according to another embodiment shown in FIG. 4-A, may be arranged in parallel to each other along both edge portions 34a and 34b of a mesa portion 33. In a Group III nitride based compound semiconductor, a semiconductor layer is often formed on a sapphire substrate serving as the substrate 10. In this case, since the n-type electrode layer 19 and the p-type electrode layer 18 are arranged to have the same direction, at an edge portion 36 on a side parallel to an array of the p-type electrode layer 18 and the n-type electrode layer 19 of the mesa portion 33, concentration of an electric field caused by a current flowing from the p-type electrode layer 18 does not easily occur. For this reason, when the insulating film 17 covers edge portions 34a and 34b on a side vertical to the array of the p-type electrode layer 18 and the n-type electrode layer 19, concentration of an electric field can be sufficiently suppressed. In this case, in the mask layer etching step, the resist pattern 22 (FIG. 1-B) may be formed in the form of stripes.

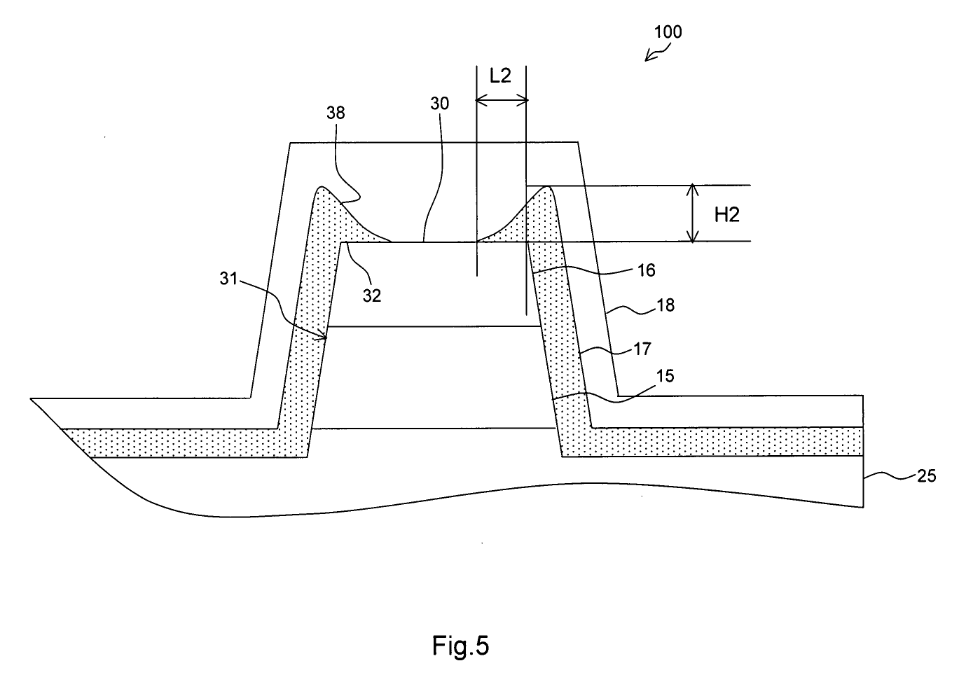

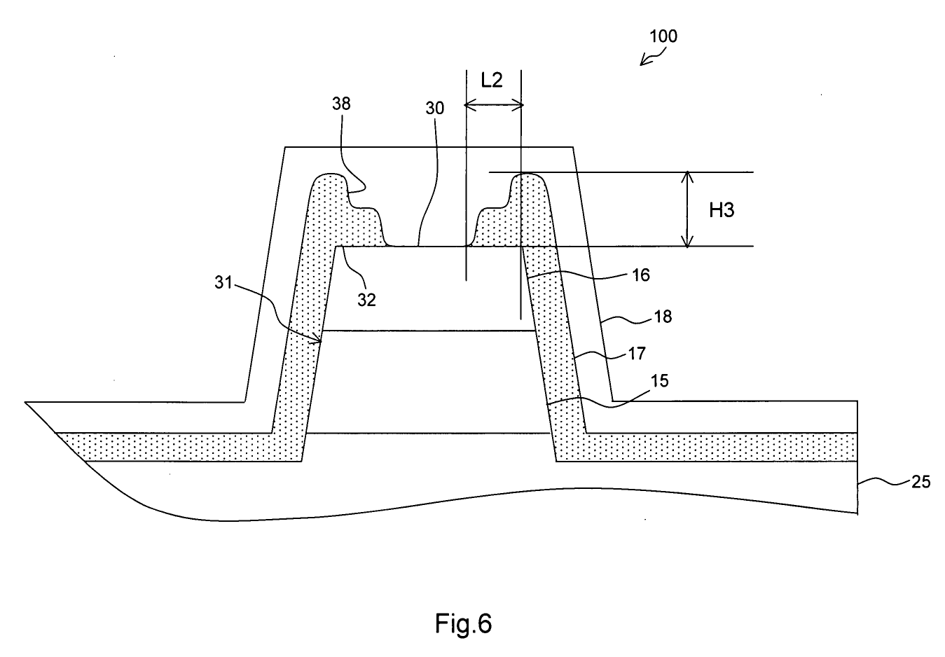

A shape of an inner wall surface 38 along the upper surface 30 of the mesa portion 31 of the insulating film 17 will be described in detail. FIGS. 5 and 6 are enlarged schematic sectional diagrams of mesa portions of the semiconductor light emitting apparatus according to the embodiment.

The inner wall surface 38 along the upper surface 30 of the mesa portion 31 of the insulating film 17, as shown in FIG. 5, is preferably inclined to be widened toward the upper side of the mesa portion 31. When the wall surface 38 is inclined to be widened toward the upper side of the mesa portion 31, a smooth curve is obtained between the upper surface 30 of the mesa portion 31 and the wall surface 38. For this reason, concentration of stress caused by a difference between thermal expansions of the insulating film 17 and the upper surface 30 of the mesa portion 31 does not occur. For this reason, the semiconductor light emitting apparatus 100 can achieve a long life.

The wall surface 38 is preferably formed such that a ratio of a height H2 of the insulating film 17 to a width L2 of the edge portion 32 of the insulating film 17 (i.e., a value of H2/L2) is 3 or less to obtain an effect that suppresses concentration of stress. An inclination angle of the wall surface 38 is adjusted to a predetermined angle by a layer thickness H1 (FIG. 1-A and FIG. 2-A) of the first mask layer 20 formed in the mask layer forming step and a depth L1 (FIG. 2-A) of the groove portion 37 formed in the side etching step. The layer thickness H1 (FIG. 1-A and FIG. 2-A) of the first mask layer 20 in the mask layer forming step is set at 10 nm or more and 500 nm or less. The depth L1 (FIG. 2-A) of the groove portion 37 in the side etching step is determined by adjusting etching time such that a ratio of the depth L1 of the groove portion 37 to the layer thickness H1 of the first mask layer 20 is 3 or less in accordance with the layer thickness H1 of the first mask layer 20. In this case, the layer thickness of the first mask layer 20 is set at 100 nm, and the layer thickness of the second mask layer 21 is set at 200 nm, and the mesa portion 31 is dipped in a buffered fluorinated acid having a concentration of 10% and serving as an etching solution for about 60 seconds to perform wet etching. In this case, the groove portion 37 having a depth of 0.2 μm can be formed.

The wall surface 38 preferably has a two-step shape as in another embodiment shown in FIG. 6. When the wall surface 38 has the two-step shape, a thickness H3 of the insulating film 17 between the edge portion 32 of the mesa portion 31 and the p-type electrode layer 18 can be increased. For this reason, the insulating property of the insulating film 17 between the p-type electrode layer 18 and the edge portion of the mesa portion 31 is made sufficient to make it possible to improve an effect that suppressing concentration of an electric field on the edge portion 32 of the mesa portion 31. The wall surface 38 having the two-step shape can have a predetermined shape because the layer thickness H1 (FIG. 1-A and FIG. 2-A) formed in the mask layer forming step and the depth L1 (FIG. 2-A) of the groove portion formed in the side etching step are adjusted. When the wall surface 38 having the two-step shape is obtained, the layer thickness H1 (FIG. 1-A and FIG. 2-A) of the first mask layer 20 in the mask layer forming step is preferably set at a value larger than 100 nm.

Furthermore, the insulating film 17 is a contact portion between the mesa portion 31 of the insulating film 17 and the upper surface 30. A width L2 (FIGS. 3-A to 6) of the edge portion 32 of the upper surface 30 of the mesa portion 31 preferably exceeds 0 and is preferably 0.5 μm or less. When the width of the edge portion 32 of the insulating film 17 exceeds 0 and is 0.5 μm or less, concentration of an electric field on the edge portion 32 of the mesa portion 31 on the p-GaN contact layer 16 can be efficiently suppressed while keeping a sufficient amount of current from the p-type electrode layer 18 to the p-GaN contact layer 16 serving as a p-type semiconductor layer.

The insulating film 17 is preferably made of a metal oxide or a semimetal oxide. For example, as the insulating film 17, ZrO₂ or Al₂O₃ can be applied. Since the metal oxide and the semimetal oxide are good in insulating property, concentration of an electric field on the edge portion 32 of the mesa portion 31 can be efficiently suppressed.

As described above, in the method of manufacturing the semiconductor light emitting apparatus 100 according to the embodiment, a groove portion is formed in the manufacturing steps, and the insulating film 17 is formed to be filled in the groove portion to make it possible to form a seam in the insulating film 17. For this reason, a yield of liftoff to the p-GaN contact layer 16 can be improved. Furthermore, a semiconductor light emitting apparatus in which the edge portion 32 of the mesa portion 31 on the p-GaN contact layer 16 is covered with the insulating film 17 can be manufactured. In addition, depending on the layer thickness H1 (FIG. 1-A) of the first mask layer 20 in the mask layer forming step, the inner wall surface 38 along the upper surface 30 of the mesa portion 31 of the insulating film 17 can be inclined to be widened toward the upper side of the mesa portion 31.

On the other hand, in the semiconductor light emitting apparatus 100 in which the edge portion 32 of the mesa portion 31 on the p-GaN contact layer 16 is covered with the insulating film 17, since concentration of an electric field caused by a current from the p-type electrode layer 18 to the edge portion 32 of the mesa portion 31 is suppressed, a withstand voltage increases. For this reason, the semiconductor light emitting apparatus 100 can be high-powered. Furthermore, when the inner wall surface 38 along the upper surface 30 of the mesa portion 31 of the insulating film 17 is inclined to be widened toward the upper side of the mesa portion 31, concentration of stress caused by a difference between thermal expansions of the insulating film 17 and the upper surface 30 of the mesa portion 31 does not occur. For this reason, the semiconductor light emitting apparatus 100 can achieve a long life.

### Second Embodiment

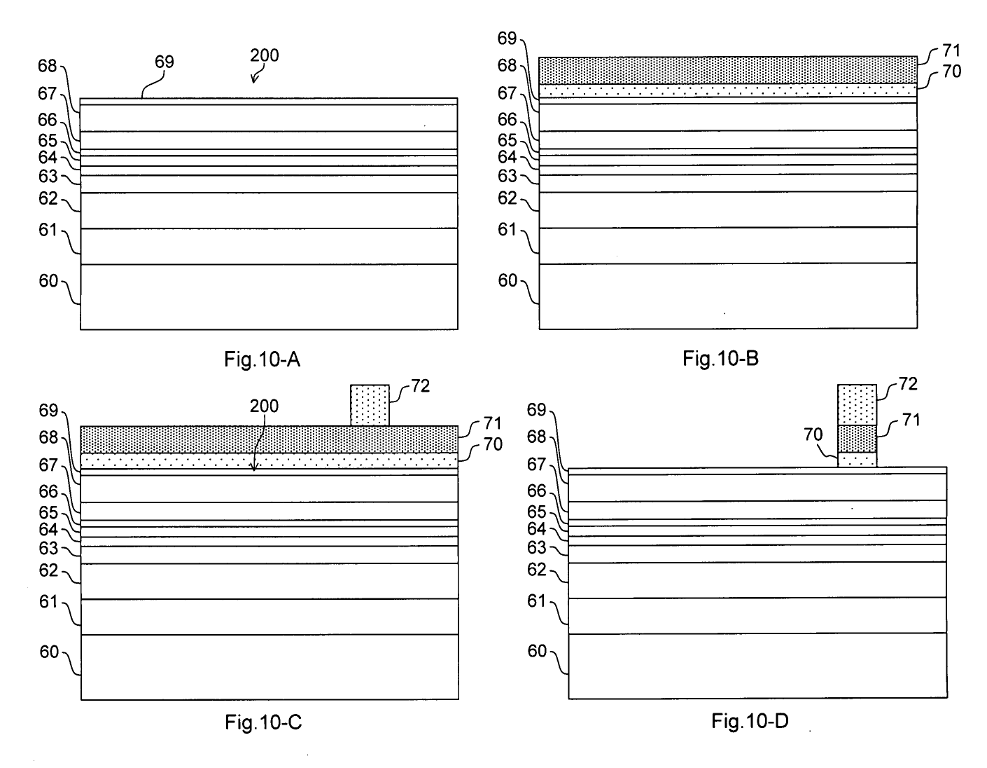

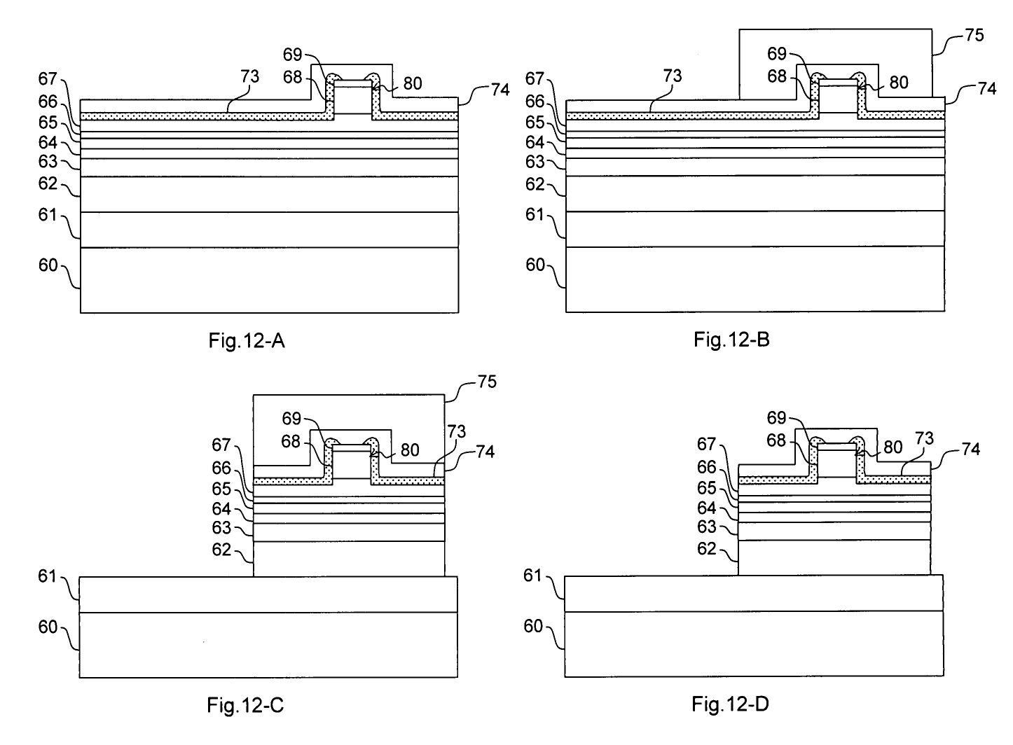

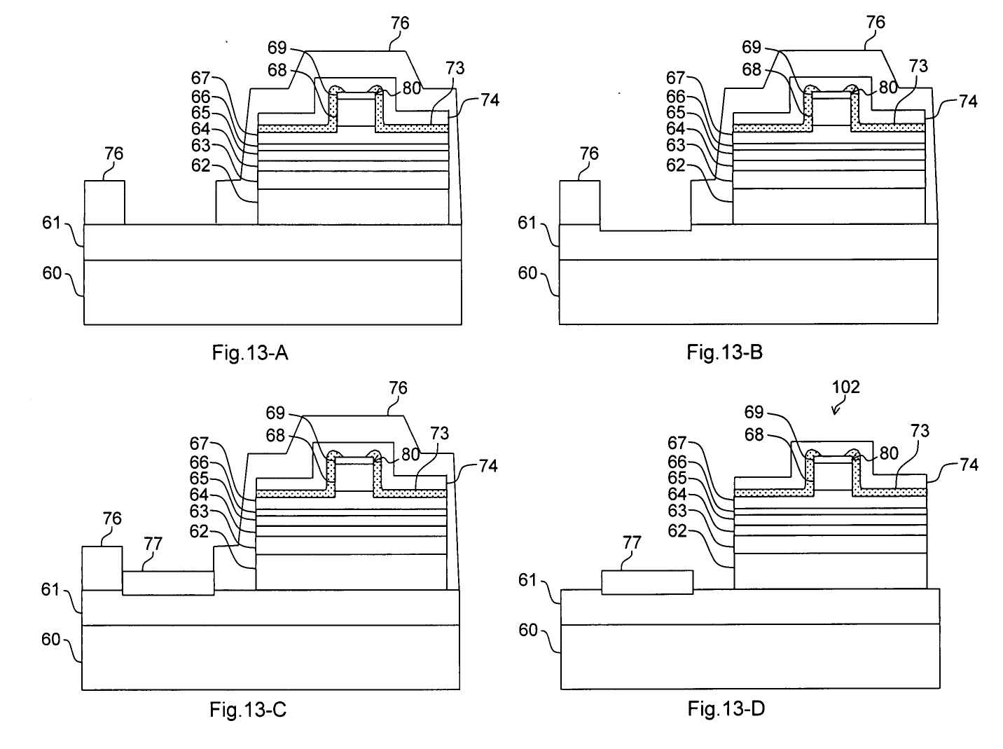

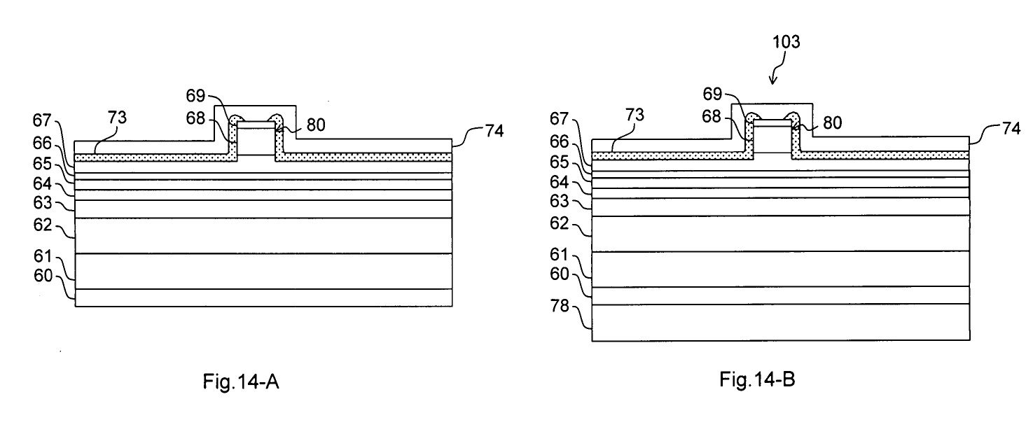

Another embodiment of a method of manufacturing a semiconductor light emitting apparatus will be described below. FIGS. 10-A to 13-D are schematic diagrams showing steps performed until a p-type electrode layer and an n-type electrode layer are formed on a wafer of a Group III nitride based compound semiconductor expressed by AlₓGa_{y}In_{1-x-y}N (where 0≦x≦1, 0≦y≦1, 0≦x+y≦1) to complete a semiconductor light emitting apparatus in the method of manufacturing a semiconductor light emitting apparatus according to the embodiment. FIGS. 14-A and 14B show schematic diagrams of the steps in manufacturing a semiconductor light emitting apparatus according to another embodiment. In FIGS. 10A to 13D, FIGS. 11-A to 11-D, FIGS. 12-A to 12-D, and FIGS. 13A to 13D show schematic sectional diagrams of the semiconductor light emitting apparatus in respective steps. FIGS. 14-A and 14-B show schematic sectional diagrams of the semiconductor light emitting apparatus in the respective steps. In FIGS. 10A to 14B, only a single semiconductor light emitting apparatus is shown. However, the method can be extended to be also applied to a method of simultaneously manufacturing a plurality of semiconductor light emitting apparatuses as in the first embodiment.

(Wafer Forming Step)

In the method of manufacturing a semiconductor light emitting apparatus according to the embodiment, a semiconductor light emitting apparatus having a Group III nitride based compound semiconductor expressed by AlₓGa_{y}In_{1-x-y}N (where 0≦x≦1, 0≦y≦1, 0≦x+y≦1) is manufactured. As shown in FIG. 10-A, n-type semiconductor layers (n-GaN buffer layer 61, n-AlGaN clad layer 62, and n-GaN guide layer 63) sequentially arranged on a GaN substrate 60 serving as a substrate, active layers (InGaN super lattice light emitting layer 64 and InGaN multiple quantum well layer 65), and p-type semiconductor layers (p-AlGaN electron block layer 66, p-GaN guide layer 67, p-AlGaN clad layer 68, and p-GaN contact layer 69) are formed to obtain a wafer 200.

Conductivity types, composition formulas, composition rates, and layer thicknesses of the layers of the wafer 200 of the Group III nitride based compound semiconductor shown in FIG. 10-A will be described below. The explanation described here is an example of the configuration of the wafer 200.

In the embodiment, the n-GaN buffer layer 61 and the n-GaN guide layer 63 are layers expressed by a composition formula GaN, and the layer thicknesses of the layers are set at 4000 nm and 100 nm, respectively. As the n-AlGaN clad layer 62, a layer expressed by a composition formula AlₓGa₁₋ₓN (x: 8%) and having a layer thickness of 1200 nm is used.

As the InGaN super lattice light emitting layer 64 which partially constitutes the active layers, a layer expressed by an n-type composition formula InₓGa₁₋ₓN/GaN (x:2/0%) and having a layer thickness of ½ nm is used. As the InGaN multiple quantum well layer 65, layers each expressed by an n-type composition formula GaN and each having a layer thickness of 9 nm and layer each expressed by an intrinsic composition formula InₓGa₁₋ₓN (x: 7%) and each having a layer thickness of 3 nm are alternately stacked from the GaN substrate 60 side. The total numbers of respective layers are set at 4 layers and 3 layers, respectively.

As the p-AlGaN electron block layer 66, a layer obtained by stacking a layer expressed by an intrinsic composition formula AlₓGa₁₋ₓN (x: 23%) and a layer thickness of 10 nm and a layer expressed by a p-type composition formula AlₓGa₁₋ₓN (x: 23%) and having a layer thickness of 15 nm is used.

As the p-GaN guide layer 67, a layer expressed by a composition formula GaN and having a layer thickness of 100 nm is used. The layer may be intrinsic.

As the p-AlGaN clad layer 68, a layer expressed by a composition formula AlₓGa₁₋ₓN (x: 8%) and having a layer thickness of 400 nm is used. As the p-GaN contact layer 69, a layer expressed by a composition formula GaN and a layer thickness of 100 nm is used.

(Mask Layer Forming Step)

On the wafer 200 shown in FIG. 10-A, as shown in FIG. 10-B, two mask layers (first mask layer 70 and second mask layer 71) are formed from a side near the p-GaN contact layer 69 in descending order of etching rates.

In this manner, as the two mask layers, the first mask layer 70 having a high etching rate and the second mask layer 71 are sequentially formed from the side near the p-GaN contact layer 69, so that a side surface of the first mask layer 70 having the high etching rate is selectively etched in the side etching step (will be described later) to make it possible to form a groove portion in the side surface.

As described in the first embodiment, a ratio of etching rates of the first mask layer 70 having the high etching rate and the second mask layer 71 having a low etching ratio is preferably set at 5 or more. More preferably, the ratio of etching rates is set at 10 or more.

As described in the first embodiment, as a combination of the first mask layer 70 and the second mask layer 71, any one of combinations of: for example, an SiO₂ layer formed by spin coating or thermal solidification or ultraviolet curing after the spin coating and an SiO₂ layer formed by sputtering; an SiO₂ layer formed by spin coating or thermal solidification or ultraviolet curing after the spin coating and an SiO₂ layer formed by a plasma chemical vapor growing method; an SiO₂ layer formed by spin coating or thermal solidification or ultraviolet curing after the spin coating and an SiN layer formed by sputtering; an SiO₂ layer formed by spin coating or thermal solidification or ultraviolet curing after the spin coating and an SiN layer formed by a plasma chemical vapor growing method; an SiO₂ layer formed by spin coating or thermal solidification or ultraviolet curing after the spin coating and a ZrO₂ layer formed by sputtering; a ZnO layer formed by laser abrasion and an SiO₂ layer formed by sputtering; a ZnO layer formed by laser abrasion and an SiO₂ layer formed by a plasma chemical vapor growing method; a ZnO layer formed by laser abrasion and an SiN layer formed by sputtering; a ZnO layer formed by laser abrasion and an SiN layer formed by sputtering; a ZnO layer formed by laser abrasion and an SiN layer formed by a plasma chemical vapor growing method; and a ZnO layer formed by laser abrasion and a ZrO₂ layer formed by sputtering can be used.

As described in the first embodiment, the first mask layer 70 having a high etching rate preferably has a layer thickness of 10 nm or more and 500 nm or less.

(Mask Layer Etching Step)

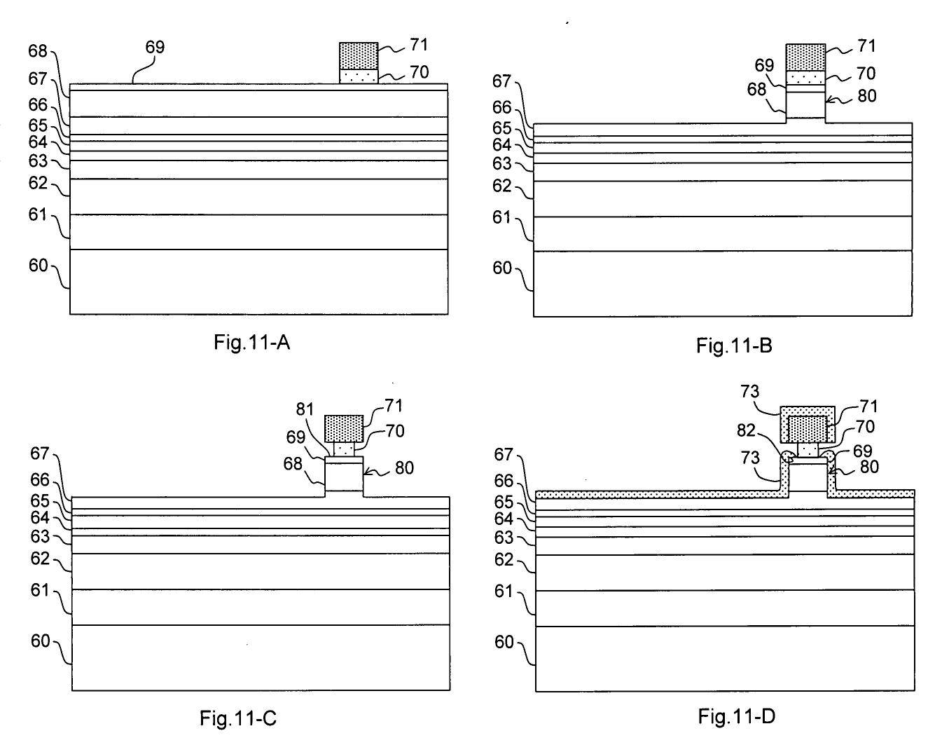

On the first mask layer 70 and the second mask layer 71 formed in the mask layer forming step, as shown in FIG. 10-C, a predetermined resist pattern 72 is formed. By using the formed resist pattern 72 as a mask, as shown in FIG. 10-D, both the first mask layer 70 and the second mask layer 71 are etched. Thereafter, the resist pattern 72 is peeled from the two layers, i.e., the first mask layer 70 and the second mask layer 71 (FIG. 11-A).

(Semiconductor Layer Etching Step)

The resist pattern formed by the two layers, i.e., the first mask layer 70 and the second mask layer 71 formed in the mask layer etching step is used as a mask to dry-etch the p-GaN contact layer 69 the p-AlGaN clad layer 68, and a part of the p-GaN guide layer 67 as shown in FIG. 11-B. In this case, when the layer thickness of the second mask layer 71 is small, the second mask layer 71 is completely removed in the dry etching. For this reason, the layer thickness of the second mask layer 71 is set at a predetermined value or more in the mask layer forming step. In this step, a mesa portion 80 electrically connected to a p-type electrode layer (will be described later) is formed on the p-GaN contact layer 69.

(Side Etching Step)

As shown in FIG. 11-C, a side surface of the first mask layer 70 of the two mask layers is selectively etched to form a groove portion 81 which partially exposes the p-GaN contact layer 69. In the embodiment, a buffered fluorinated acid is used as an etching solution, and wet etching is performed such that the mesa portion 80 shown in FIG. 11-C is dipped in the etching solution for a predetermined period of time, thereby forming the groove portion 81. A depth of the groove portion 81 is determined depending on an amount of filling of an insulating film formed in the insulating forming step (will be described later) as described in the first embodiment.

(Insulating Film Forming Step)

An insulating film 73 is formed so as to cover the p-GaN contact layer 69 exposed in the groove portion 81 formed by the side etching step (FIG. 11-D). In the embodiment, the insulating film 73 is formed by the sputtering, the plasma chemical vapor growing method, or the laser abrasion. By these methods, as shown in FIG. 11-D, the insulating film 73 is formed to be filled in the groove portion 81. For this reason, the insulating film 73 is prevented from coating the entire surfaces of the first mask layer 70 and the second mask layer 71 to make it possible to form a seam in the insulating film 73. More specifically, a seam is formed between the insulating film 73 which covers the p-GaN contact layer 69 exposed in the groove portion 81 and the insulating film 73 covering the second mask layer 71. For this reason, in the mask layer removing step (will be described later), when the first mask layer 70 and the second mask layer 71 are removed from the p-GaN contact layer 69, the first mask layer 70 and the second mask layer 71 can be lifted off at the seam. Therefore, a yield of liftoff to the p-GaN contact layer 69 can be increased. Furthermore, the insulating film 73 is filled in the groove portion 81, so that a semiconductor light emitting apparatus in which an edge portion 82 of the mesa portion 80 formed in the semiconductor layer etching step is covered with the insulating film 73 to suppress concentration of an electric field on the edge portion 82 so as to increase a withstand voltage can be manufactured. In this case, as described in the first embodiment, the insulating film 73 is preferably made of a metal oxide or a semimetal oxide which is good in insulating property.

(Mask Layer Removing Step)

As shown described in the first embodiment, for example, the mesa portion 80 shown in FIG. 11-D is dipped in the buffered fluorinated acid to lift off the remaining first mask layer 70 and the remaining second mask layer 71 from the p-GaN contact layer 69.

(Electrode Layer Forming Step)

A p-type electrode layer 74 is formed so as to cover the entire surface of the p-GaN contact layer 69 exposed in the mask layer removing step as shown in FIG. 12-A.

As shown in FIG. 12-B, a photoresist 75 is formed so as to cover the p-type electrode layer 74 on the mesa portion 80, and the p-type electrode layer 74 and the insulating film 73 are dry-etched together with the semiconductor layer up to the n-GaN buffer layer 61 by using the photoresist 75 as a mask. The photoresist 75 is peeled from the p-type electrode layer 74 (FIG. 12-D).

A photoresist 76 is formed so as to cover the n-GaN buffer layer 61 and the n-AlGaN clad layer 62 to the p-type electrode layer 74 except for a portion on which an n-type electrode layer will be formed later (FIG. 13-D). The n-GaN buffer layer 61 is dry-etched by using the photoresist 76 as a mask (FIG. 13-B). Thereafter, an n-type electrode layer 77 is formed on an etching portion of the n-GaN buffer layer 61 (FIG. 13-C), and the photoresist 76 is peeled to obtain a semiconductor light emitting apparatus 102 shown in FIG. 13-D.

As shown in FIG. 12-A, after the p-type electrode layer 74 is formed, as shown in FIG. 14-A, the GaN substrate 60 may be reduced in thickness by lapping, and as shown in FIG. 14-B, an n-type electrode layer 78 may be formed on a lower surface of the GaN substrate 60 to obtain a semiconductor light emitting apparatus 103. In this case, as shown in FIG. 14-A, since the mesa portion 80 is arranged at an approximate center of the semiconductor light emitting apparatus, the resist pattern 72 can be formed at an approximate center of the wafer 200 (FIG. 12-A). Functions of the respective layers of the semiconductor light emitting apparatus 102 and the semiconductor light emitting apparatus 103 manufactured as described above are the same as those in the semiconductor light emitting apparatuses 100 and 101 with respect to corresponding portions shown in FIG. 3-A and 3-B and FIG. 4-A and 4-B. Functions of the insulating films of the semiconductor light emitting apparatuses 102 and 103 are the same as those in the semiconductor light emitting apparatuses 100 and 101 with respect to corresponding portions shown in FIGS. 3-A and 3-B and FIGS. 4-A and 4-B. Therefore, the semiconductor light emitting apparatuses 102 and 103 have the same effects as those of the semiconductor light emitting apparatuses 100 and 101 described in FIGS. 3-A and 3-B and FIGS. 4-A and 4-B.

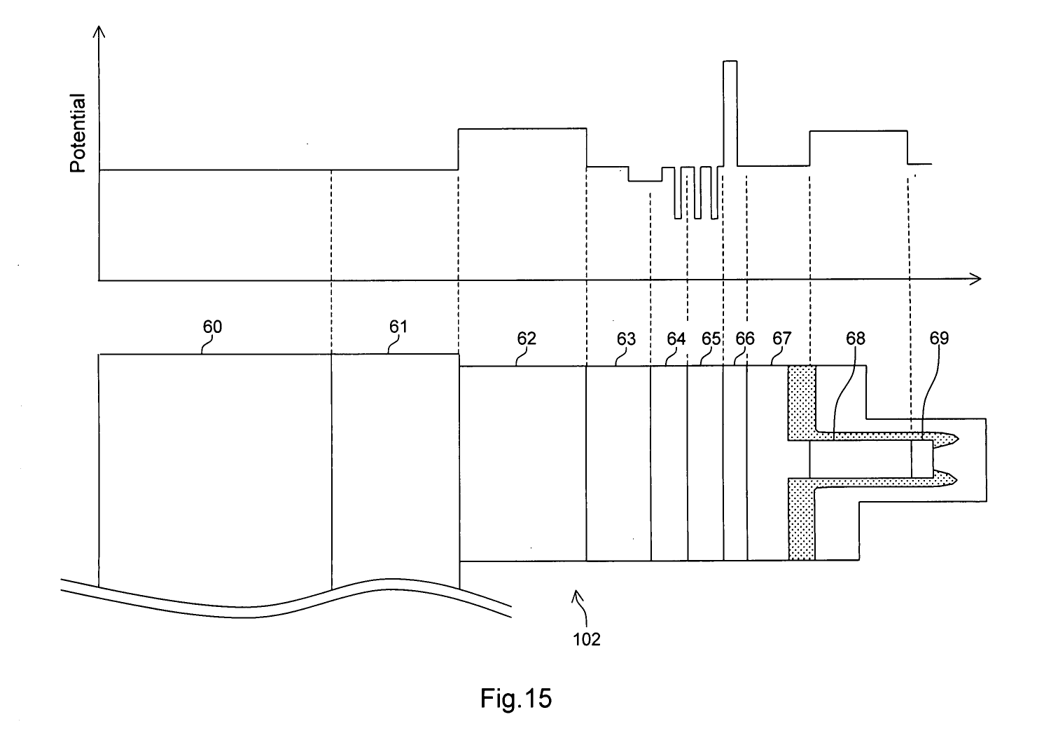

In this case, FIG. 15 shows potentials of respective layers of the semiconductor light emitting apparatus 102 shown in FIG. 13-D. As the potentials shown in FIG. 15, relative potentials of the respective layers are shown.

A semiconductor light emitting apparatus according to the present invention can be used as a laser diode to be mounted on a lighting apparatus, a communication apparatus, a sensor, a display device, and other devices.

What is claimed is:

1. A method of manufacturing a semiconductor light emitting apparatus having:
the mask layer forming step of forming two mask layers on a p-type semiconductor layer of a Group III nitride based compound semiconductor in which an n-type semiconductor layer, an active layer, and the p-type semiconductor layer are sequentially arranged on a substrate and which is expressed by AlₓGa_{y}In_{1-x-y}N (where 0≦x≦1, 0≦y≦1, 0≦x+y≦1) in descending order of etching rates from a side near the p-type semiconductor layer;
the mask layer etching step of forming a predetermined resist pattern on the two mask layers formed in the mask layer forming step, etching both the two mask layers by using the formed resist pattern as a mask, and peeling the resist pattern from the two mask layers;
the semiconductor layer etching step of etching the p-type semiconductor layer by using, as a mask, a resist pattern obtained by the two mask layers formed in the mask layer etching step;
the side etching step of, after the semiconductor layer etching step, selectively etching a side surface of a mask layer having a high etching rate of the two mask layers to form a groove portion from which a part of the p-type semiconductor layer is exposed;
the insulating film forming step of forming an insulating film to cover the exposed p-type semiconductor layer of the groove portion formed in the side etching step;
the mask layer removing step of, after the insulating film forming step, removing the two remaining mask layers from the p-type semiconductor layer; and
the electrode layer forming step of forming an electrode layer so as to cover an entire surface of the p-type semiconductor layer exposed in the mask layer removing step.

2. The method of manufacturing a semiconductor light emitting apparatus according to claim 1,
wherein a ratio of etching rates of the two mask layers is set at not less than 5.

3. The method of manufacturing a semiconductor light emitting apparatus according to claim 1,
wherein, as a mask layer having a high etching rate of the two mask layers, an oxide or a nitride which is formed by spin coating by performing thermal solidification or ultraviolet curing after the spin coating or laser abrasion is used, and as a mask layer having a low etching rate of the two mask layers, an oxide or a nitride which is formed by sputtering or a plasma chemical vapor growing method is used.

4. The method of manufacturing a semiconductor light emitting apparatus according to claim 1,
wherein, in the mask layer forming step, a layer thickness of the mask layer having a high etching rate is not less than 10 nm and not more than 500 nm.

5. The method of manufacturing a semiconductor light emitting apparatus according to claim 2,
wherein, in the mask layer forming step, a layer thickness of the mask layer having a high etching rate is not less than 10 nm and not more than 500 nm.

6. The method of manufacturing a semiconductor light emitting apparatus according to claim 3,
wherein, in the mask layer forming step, a layer thickness of the mask layer having a high etching rate is not less than 10 nm and not more than 500 nm.

7. The method of manufacturing a semiconductor light emitting apparatus according to claim 1,
wherein, in the insulating film forming step, the insulating film is made of an oxide or a nitride of a metal or a semimetal.

8. The method of manufacturing a semiconductor light emitting apparatus according to claim 2,
wherein, in the insulating film forming step, the insulating film is made of an oxide or a nitride of a metal or a semimetal.

9. The method of manufacturing a semiconductor light emitting apparatus according to claim 3,
wherein, in the insulating film forming step, the insulating film is made of an oxide or a nitride of a metal or a semimetal.

10. A semiconductor light emitting apparatus comprises: a substrate, an n-type semiconductor layer arranged on the substrate, an active layer arranged on the n-type semiconductor layer, a p-type semiconductor layer which is arranged on the active layer and on which a mesa portion projecting above the active layer, an insulating film which covers the mesa portion from an inner side along the edge of the upper surface to a side surface of the mesa portion so as to expose the upper surface of the mesa portion, and an electrode layer which covers the mesa portion from above the insulating film and which is electrically connected to the p-type semiconductor layer, wherein the n-type semiconductor layer, the active layer, and the p-type semiconductor layer is made of a Group III nitride based compound semiconductor expressed by AlₓGa_{y}In_{1-x-y}N (where 0≦x≦1, 0≦y≦1, 0≦x+y≦1).

11. The semiconductor light emitting apparatus according to claim 10,
wherein an inner wall surface along the upper surface of the mesa portion of the insulating film is inclined to be widened toward the upper side of the mesa portion.

12. The semiconductor light emitting apparatus according to claim 11,
wherein the wall surface has a two-step shape.

13. The semiconductor light emitting apparatus according to claim 10,
wherein a width of a contact portion between the insulating film and the upper surface of the mesa portion from the edge of the upper surface of the mesa portion exceeds 0 and is not more than 0.5 μm.

14. The semiconductor light emitting apparatus according to claim 11,
wherein a width of a contact portion between the insulating film and the upper surface of the mesa portion from the edge of the upper surface of the mesa portion exceeds 0 and is not more than 0.5 μm.

15. The semiconductor light emitting apparatus according to claim 12,
wherein a width of a contact portion between the insulating film and the upper surface of the mesa portion from the edge of the upper surface of the mesa portion exceeds 0 and is not more than 0.5 μm.

16. The semiconductor light emitting apparatus according to claim 10,
wherein the insulating film is made of an oxide or a nitride of a metal or a semimetal.

17. The semiconductor light emitting apparatus according to claim 11,
wherein the insulating film is made of an oxide or a nitride of a metal or a semimetal.

18. The semiconductor light emitting apparatus according to claim 12,
wherein the insulating film is made of an oxide or a nitride of a metal or a semimetal.
